(19) United States
(12) Patent Application Publication
(10) Pub. No.: US 2025/0347725 A1
(43) Pub. Date: Nov. 13, 2025

(54) MEASUREMENT DEVICE AND MEASUREMENT METHOD THEREOF

(71) Applicant: ANRITSU CORPORATION, Kanagawa (JP)

(72) Inventors: Takasumi IKEBE, Kanagawa (JP); Akihito YOSHITO, Kanagawa (JP); Keisuke SUZUKI, Kanagawa (JP)

(21) Appl. No.: 19/202,465

(22) Filed: May 8, 2025

(30) Foreign Application Priority Data
May 13, 2024 (JP) 2024-077994

(51) Int. Cl. G01R 29/08

(52) U.S. Cl. CPC G01R 29/0871

(57) ABSTRACT

A measurement device capable of reducing noise during EVM measurement in a case where a level of an input signal changes is provided. A measurement device includes a first input port, a first variable attenuator that attenuates a signal level of an uplink signal input into the first input port in accordance with a set input level, a first AD converter that converts an analog signal attenuated by the first variable attenuator into a digital signal, a signal analysis unit that performs modulation analysis on a section to be measured in the digital signal output from the first AD converter, and a control unit that, in measuring an input signal that consists of a plurality of sections and that has different signal levels in each section, changes the input level in accordance with a section to be measured during measurement of each section.

### TECHNICAL FIELD

The present invention relates to a measurement device that measures a radio wave transmitted by a radio terminal of a mobile communication system.

### BACKGROUND ART

A radio terminal that has been developed in recent years and that transmits and receives a radio signal corresponding to IEEE 802.11ad, 5G cellular, or the like using a wideband signal of a millimeter wave band is subjected to a performance test for measuring an output level and reception sensitivity of a transmitted radio wave determined for each communication standard and determining whether or not a predetermined reference is satisfied with respect to a radio communication antenna included in the radio terminal.

Items to be measured include an error vector magnitude (EVM). The EVM indicates deviation between a measured signal and a theoretical modulated signal for a signal to which digital modulation is applied.

Patent Document 1 discloses estimating a characteristic of a phase error using only signal data corresponding to a symbol having an EVM smaller than a predetermined reference value and correcting the phase error based on the characteristic.

### RELATED ART DOCUMENT

### Patent Document

[Patent Document 1] JP-A-2023-17519

### DISCLOSURE OF THE INVENTION

### Problem that the Invention is to Solve

In a case where a signal to be measured is fixed (the same power and the same modulation performance), the EVM deteriorates as noise in a measurement device is increased. Thus, high-reliability measurement requires sufficiently low noise in the measurement device.

The measurement device has a function of reducing the noise by setting an input level in accordance with a level of an input signal to attenuate the input signal. In the measurement device, the input signal is distorted unless the input level is set to be higher than the level of the input signal. However, the noise in the measurement device tends to increase as the input level is increased. In a case where the input level does not match the level of the input signal, an effect of reducing the noise is not sufficiently obtained.

In the 3rd Generation Partnership Project (3GPP) standard, the EVM of a symbol in a case where the level of the input signal changes is also to be measured.

In such a case, the input level is required to be set to a level of a high-level section of the input signal. However, in this case, the signal of a low-level section of the input signal is measured with a setting of the input level higher than the level. Thus, there is room for improvement for the noise in the measurement device in the low-level section of the input signal.

Therefore, an object of the present invention is to provide a measurement device capable of reducing noise during EVM measurement in a case where a level of an input signal changes, by changing an input level in accordance with the level of the input signal.

### Means for Solving the Problem

A measurement device of the present invention includes at least one input port (31, 34), a variable attenuator corresponding to the input port (32, 35), and a control unit (7) that attenuates a signal input into the input port via the variable attenuator by an attenuation amount corresponding to a set input level, in which, in measuring an input signal that consists of a plurality of sections and that has different signal levels in each section, the control unit changes the input level in accordance with a section to be measured during measurement of each section.

According to this configuration, in measuring the input signal that consists of the plurality of sections and that has different signal levels in each section, the input level is changed in accordance with the section to be measured during measurement of each section. Thus, noise during EVM measurement in a case where the level of the input signal changes can be reduced.

A measurement device of the present invention includes at least two input ports (31, 34), variable attenuators corresponding to the input ports (32, 35), and a control unit (7) that attenuates a signal input into the input ports via the variable attenuators by an attenuation amount corresponding to a set input level, in which, in measuring an input signal that consists of a plurality of sections and that has different signal levels in each section, the input signal to be measured is distributed to all of the input ports, and the control unit sets an input level corresponding to each section in each input port and measures each section using an input signal of an input port for which the input level corresponding to each section is set.

According to this configuration, in measuring the input signal that consists of the plurality of sections and that has different signal levels in each section, the input signal to be measured is distributed to all of the input ports, the input level corresponding to each section is set in each input port, and each section is measured using the input signal of the input port for which the input level corresponding to each section is set. Thus, noise during EVM measurement in a case where the level of the input signal changes can be reduced.

A measurement method of the present invention is a measurement method of a measurement device including at least one input port (31, 34), a variable attenuator (32, 35) corresponding to the input port, and a control unit (7) that attenuates a signal input into the input port via the variable attenuator by an attenuation amount corresponding to a set input level, the method including a step of changing, in measuring an input signal that consists of a plurality of sections and that has different signal levels in each section, the input level in accordance with a section to be measured during measurement of each section.

According to this configuration, in measuring the input signal that consists of the plurality of sections and that has different signal levels in each section, the input level is changed in accordance with the section to be measured during measurement of each section. Thus, noise during EVM measurement in a case where the level of the input signal changes can be reduced.

A measurement method of the present invention is a measurement method of a measurement device including at least two input ports (31, 34), variable attenuators (32, 35) corresponding to the input ports, and a control unit (7) that attenuates a signal input into the input ports via the variable attenuators by an attenuation amount corresponding to a set input level, the method including a step of distributing, in measuring an input signal that consists of a plurality of sections and that has different signal levels in each section, the input signal to be measured to all of the input ports, a step of setting an input level corresponding to each section in each input port, and a step of measuring each section using an input signal of an input port for which the input level corresponding to each section is set.

According to this configuration, in measuring the input signal that consists of the plurality of sections and that has different signal levels in each section, the input signal to be measured is distributed to all of the input ports, the input level corresponding to each section is set in each input port, and each section is measured using the input signal of the input port for which the input level corresponding to each section is set. Thus, noise during EVM measurement in a case where the level of the input signal changes can be reduced.

### Advantage of the Invention

The present invention can provide a measurement device capable of reducing noise during EVM measurement in a case where a level of an input signal changes.

### BRIEF DESCRIPTION OF THE DRAWINGS

FIG. 1 is a block diagram of a measurement device according to one embodiment of the present invention.

FIG. 2 is a diagram illustrating an example of a relationship between an input level of the measurement device according to one embodiment of the present invention and noise in the device.

FIG. 3 is a diagram illustrating an example of a signal to be measured by the measurement device according to one embodiment of the present invention.

FIG. 4 is a flowchart illustrating a procedure of measurement processing of the measurement device according to one embodiment of the present invention.

FIG. 5 is a flowchart illustrating a procedure of measurement processing of the measurement device according to another aspect of one embodiment of the present invention.

### BEST MODE FOR CARRYING OUT THE INVENTION

Hereinafter, a measurement device according to an embodiment of the present invention will be described in detail with reference to the drawings.

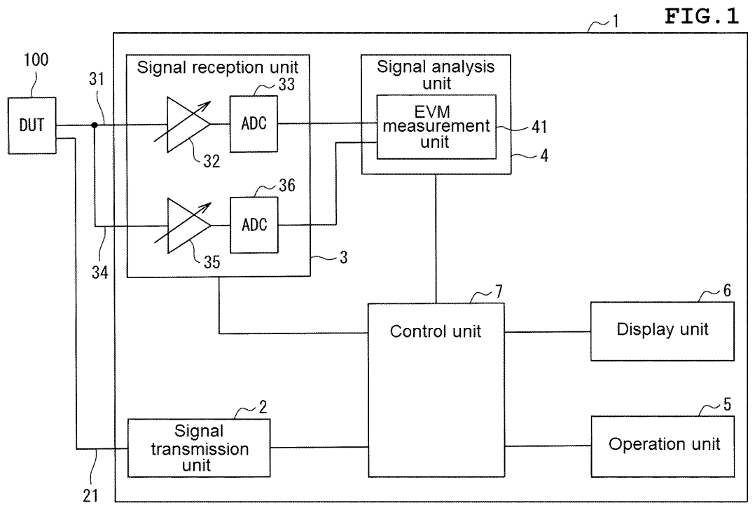

In FIG. 1, a measurement device 1 according to one embodiment of the present invention is connected to a radio terminal as a device under test (DUT) 100 in a wired manner through a coaxial cable or the like and performs a measurement test for the DUT 100 by simulating a base station. The measurement device 1 may wirelessly transmit and receive a radio frequency (RF) signal to and from the DUT 100 through an antenna.

The measurement device 1 is configured to include a signal transmission unit 2, a signal reception unit 3, a signal analysis unit 4, an operation unit 5, a display unit 6, and a control unit 7.

The signal transmission unit 2 transmits a downlink signal to the DUT 100. The signal transmission unit 2 includes an output port 21. The signal transmission unit 2 is connected to the DUT 100 through the output port 21, and the downlink signal is transmitted to the DUT 100 from the output port 21. The downlink signal includes information required for transmitting a signal via the DUT 100.

The signal reception unit 3 receives an uplink signal from the DUT 100 and converts the analog uplink signal into a digital signal.

The signal reception unit 3 includes a first input port 31 as an input port, a first variable attenuator 32, a first AD converter 33, a second input port 34 as an input port, a second variable attenuator 35, and a second AD converter 36.

The signal reception unit 3 is connected to the DUT 100 through the first input port 31 and the second input port 34, and the uplink signal from the DUT 100 is input into the first input port 31 and the second input port 34.

The uplink signal input into the first input port 31 is adjusted in signal level by the first variable attenuator 32, converted into a digital signal by the first AD converter 33, and output to the signal analysis unit 4.

The uplink signal input into the second input port 34 is adjusted in signal level by the second variable attenuator 35, converted into a digital signal by the second AD converter 36, and output to the signal analysis unit 4.

The signal analysis unit 4 performs modulation analysis on a section to be measured in the digital signal input from the signal reception unit 3.

The signal analysis unit 4 includes an EVM measurement unit 41. The EVM measurement unit 41 measures an EVM of the section to be measured in the digital signal input from the signal reception unit 3 and outputs a result to the control unit 7.

The operation unit 5 is configured with an input device such as a keyboard, a mouse, or a touch panel and outputs information or the like provided by an operation input and required for measurement to the control unit 7. The display unit 6 is configured with an image display device such as a liquid crystal display and displays an image for inputting the information required for measurement, an image showing a state during measurement, an image showing a measurement result, and the like.

The control unit 7 receives input of the information required for measurement by displaying a measurement setting screen on the display unit 6 in accordance with an instruction input into the operation unit 5 or notifies the signal transmission unit 2, the signal reception unit 3, and the signal analysis unit 4 of information for measurement based on information input into the operation unit 5 on the measurement setting screen. The control unit 7 executes measurement based on the information provided by notification by transmitting instructions to the signal transmission unit 2, the signal reception unit 3, and the signal analysis unit 4 in accordance with an instruction input into the operation unit 5 or displays the measurement result or the like on the display unit 6 based on the measurement result transmitted from the signal analysis unit 4.

The measurement device 1 is configured with a computer device (not illustrated) provided with a communication module for communicating with the DUT 100. The computer device includes a central processing unit (CPU), a read only memory (ROM), a random access memory (RAM), a storage device such as a hard disk device, an input/output port, and a touch panel (none illustrated).

A program for causing the computer device to function as the measurement device 1 is stored in the ROM and the hard disk device of the computer device. That is, the computer device functions as the measurement device 1 by executing the program stored in the ROM via the CPU using the RAM as a work region.

In the present embodiment, the signal analysis unit 4 and the control unit 7 are configured with the CPU, and the signal transmission unit 2 and the signal reception unit 3 are configured with the communication module.

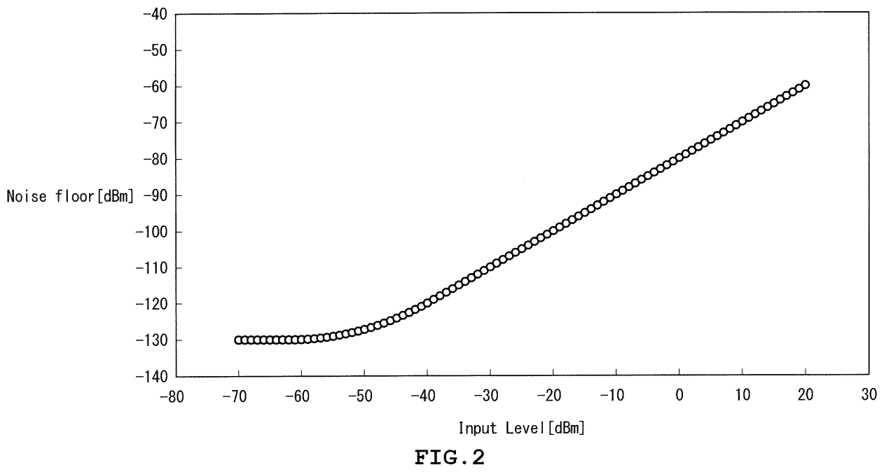

In this configuration of the measurement device 1, for example, as illustrated in FIG. 2, noise (in FIG. 2, “Noise floor” on the vertical axis) tends to increase as an input level (in FIG. 2, “Input Level” on the horizontal axis) is increased. In the measurement device 1, an input signal is distorted unless the input level is set to be higher than a level of the input signal. Thus, the measurement device 1 has a function of reducing the noise by attenuating the input signal in accordance with the input level set in accordance with the level of the input signal.

The control unit 7 sets attenuation amounts of the corresponding variable attenuators 32 and 35 of the input ports 31 and 34 of the signal reception unit 3 in accordance with the input level set by operating the operation unit 5.

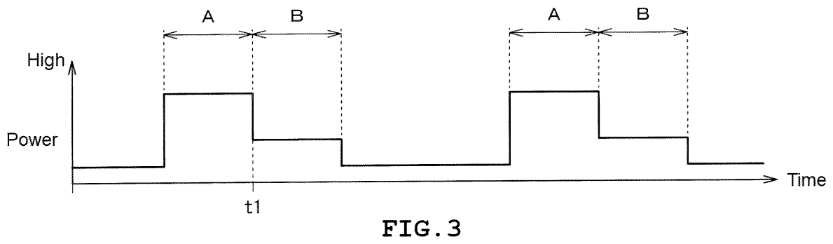

In the 3GPP standard, as indicated by time t1 in FIG. 3, the EVM is also to be measured for a symbol in a case where the level of the input signal changes.

The measurement device 1 is required to set the input level to a level of a high-level section of the input signal indicated by A in FIG. 3. However, in this case, the signal of a low-level section of the input signal indicated by B in FIG. 3 is measured with a setting of the input level higher than the level. Thus, noise during EVM measurement in the measurement device 1 is increased.

Thus, the measurement device 1 of the present embodiment reduces noise during EVM measurement in both of the high-level section and the low-level section of the input signal by switching the input level of the measurement device 1 during measurement.

In a case where a user selects a measurement setting function by operating the operation unit 5, the control unit 7, for example, sets the input level, the signal to be transmitted by the DUT 100, and the like by displaying the measurement setting screen on the display unit 6.

In setting measurement in a case where the level of the input signal changes, the control unit 7 sets the input level of the high-level section of the input signal and the input level of the low-level section of the input signal.

The control unit 7 sets the high-level section of the input signal and the low-level section of the input signal on a time axis as schedule information.

For example, the control unit 7 sets the level of the input signal on the time axis for the high-level section and the low-level section of the input signal by setting the number of resource blocks (RBs) for transmitting data.

The control unit 7 may set the input level of the high-level section of the input signal and the input level of the low-level section of the input signal in accordance with the set level of the input signal in the high-level section of the input signal and the set level of the input signal in the low-level section of the input signal.

The control unit 7 stores the set information as setting information in association with identification information.

In a case where the user makes a selection to start measurement by operating the operation unit 5 and, for example, one piece of the setting information is selected from a list of the identification information of the setting information displayed on the display unit 6, the control unit 7 starts measurement in accordance with content of the selected setting information.

The control unit 7 creates signal information indicating content of the signal to be transmitted by the DUT 100 from the setting information and transmits the signal information to the signal transmission unit 2.

In a case where the signal transmission unit 2 receives the signal information, the signal transmission unit 2 transmits a signal causing the DUT 100 to transmit the signal having the content indicated by the signal information, to the DUT 100. Accordingly, the DUT 100 transmits a signal in which the same pattern is repeated, as illustrated in FIG. 3.

For example, the signal transmission unit 2 designates the signal to be transmitted by the DUT 100 by notifying the DUT 100 of the number of allocated RBs in each section on the time axis.

The control unit 7 transmits the schedule information indicating a position of a signal to be measured on the time axis to the signal analysis unit 4 from the setting information.

In a case where the signal analysis unit 4 receives the schedule information, the signal analysis unit 4 measures the EVM at the position of the signal to be measured on the time axis in accordance with the schedule information.

The control unit 7 sets an attenuation amount corresponding to the set input level in the variable attenuators 32 and 35 of the signal reception unit 3 in accordance with the schedule information.

In performing measurement in a case where the level of the input signal changes, the control unit 7 switches the input level in accordance with the level of the input signal.

For example, as illustrated in FIG. 3, when the repeatedly received signal to be measured is received for the first time, the control unit 7 sets an attenuation amount of the input level corresponding to a first section that is the high-level section of the input signal, in the variable attenuators 32 and 35. When the signal to be measured is received for the second time, the control unit 7 sets an attenuation amount of the input level corresponding to a second section that is the low-level section of the input signal, in the variable attenuators 32 and 35.

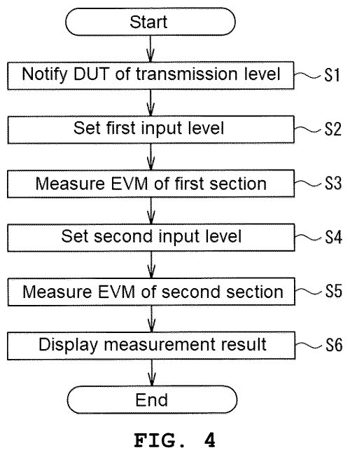

EVM measurement processing via the measurement device 1 of the above configuration according to the present embodiment will be described with reference to FIG. 4. The EVM measurement processing described below starts in a case where the user makes a selection to start EVM measurement by operating the operation unit 5.

In step S1, the control unit 7 notifies the DUT 100 of a transmission level of the RF signal via the signal transmission unit 2. After executing the processing in step S1, the control unit 7 executes the processing in step S2.

In step S2, the control unit 7 sets an attenuation amount of a first input level corresponding to the first section to be measured in the variable attenuators 32 and 35. After executing the processing in step S2, the control unit 7 executes the processing in step S3.

In step S3, the control unit 7 measures an EVM of the first section via the EVM measurement unit 41. After executing the processing in step S3, the control unit 7 executes the processing in step S4.

In step S4, the control unit 7 sets an attenuation amount of a second input level corresponding to the second section to be measured in the variable attenuators 32 and 35. After executing the processing in step S4, the control unit 7 executes the processing in step S5.

In step S5, the control unit 7 measures an EVM of the second section via the EVM measurement unit 41. After executing the processing in step S5, the control unit 7 executes the processing in step S6.

In step S6, the control unit 7 displays the measurement result on the display unit 6. After executing the processing in step S6, the control unit 7 finishes the EVM measurement processing.

In the above embodiment, in measuring the input signal of which a signal level changes, the control unit 7 performs measurement by changing the input level in accordance with the change in the level of the input signal.

Accordingly, the input level is changed in accordance with the change in the level of the input signal. Thus, noise during EVM measurement in a case where the level of the input signal changes can be reduced.

In another aspect of the present embodiment, in FIG. 1, the uplink signal from the DUT 100 is distributed to the first input port 31 and the second input port 34 by a distributor or the like.

The control unit 7 measures the first section using the uplink signal input into the first input port 31 and measures the second section using the uplink signal input into the second input port 34.

At this point, the control unit 7 sets the attenuation amount of the first input level corresponding to the first section in the variable attenuator 32 and sets the attenuation amount of the second input level corresponding to the second section in the variable attenuator 35.

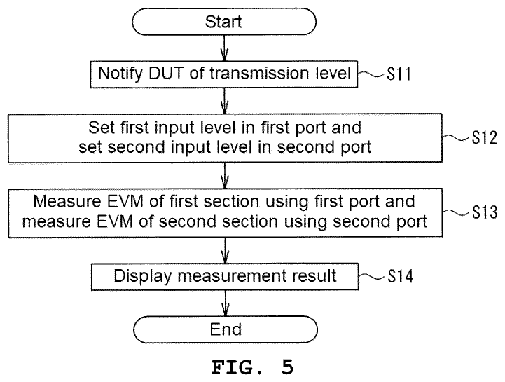

The EVM measurement processing via the measurement device 1 of the above configuration according to the other aspect of the present embodiment will be described with reference to FIG. 5. The EVM measurement processing described below starts in a case where the user makes a selection to start EVM measurement by operating the operation unit 5.

In step S11, the control unit 7 notifies the DUT 100 of the transmission level of the RF signal via the signal transmission unit 2. After executing the processing in step S11, the control unit 7 executes the processing in step S12.

In step S12, the control unit 7 sets the attenuation amount of the first input level corresponding to the first section in the first variable attenuator 32 connected to the first input port 31 and sets the attenuation amount of the second input level corresponding to the second section in the second variable attenuator 35 connected to the second input port 34. After executing the processing in step S12, the control unit 7 executes the processing in step S13.

In step S13, the control unit 7 measures the EVM of the first section via the EVM measurement unit 41 using a signal from the first AD converter 33 connected to the first input port 31 and measures the EVM of the second section via the EVM measurement unit 41 using a signal from the second AD converter 36 connected to the second input port 34. After executing the processing in step S13, the control unit 7 executes the processing in step S14.

In step S14, the control unit 7 displays the measurement result on the display unit 6. After executing the processing in step S14, the control unit 7 finishes the EVM measurement processing.

In the above embodiment, the control unit 7 sets the first input level corresponding to the first section in the first input port 31, sets the second input level corresponding to the second section in the second input port 34, measures the first section using the input signal of the first input port 31, and measures the second section using the input signal of the second input port 34.

Accordingly, the first section is measured by setting the first input level for the input signal of the first input port 31, and the second section is measured by setting the second input level for the input signal of the second input port 34. Thus, noise during EVM measurement in a case where the level of the input signal changes can be reduced.

The input signal of the first input port 31 and the input signal of the second input port 34 can be measured at the same timing, and a measurement time can be reduced.

While the embodiment of the present invention has been disclosed, changes may be made by those skilled in the art without departing from the scope of the present invention. All of such corrections and equivalents are intended to fall within the following claims.

### DESCRIPTION OF REFERENCE NUMERALS AND SIGNS

1: measurement device
2: signal transmission unit
3: signal reception unit
4: signal analysis unit
7: control unit
31: first input port (input port)
32: first variable attenuator (variable attenuator)
33: first AD converter
34: second input port (input port)
35: second variable attenuator (variable attenuator)
36: second AD converter
41: EVM measurement unit
100: DUT

What is claimed is:

1. A measurement device comprising:
at least one input port;
a variable attenuator corresponding to the input port; and
a control unit that attenuates a signal input into the input port via the variable attenuator by an attenuation amount corresponding to a set input level,
wherein, in measuring an input signal that consists of a plurality of sections and that has different signal levels in each section, the control unit changes the input level in accordance with a section to be measured during measurement of each section.

2. A measurement device comprising:
at least two input ports;
variable attenuators to the input ports; and
a control unit that attenuates a signal input into the input ports via the variable attenuators by an attenuation amount corresponding to a set input level,
wherein, in measuring an input signal that consists of a plurality of sections and that has different signal levels in each section, the input signal to be measured is distributed to all of the input ports, and
the control unit sets an input level corresponding to each section in each input port and measures each section using an input signal of an input port for which the input level corresponding to each section is set.

3. A measurement method of a measurement device including at least one input port, a variable attenuator corresponding to the input port, and a control unit that attenuates a signal input into the input port via the variable attenuator by an attenuation amount corresponding to a set input level, the method comprising:
a step of changing, in measuring an input signal that consists of a plurality of sections and that has different signal levels in each section, the input level in accordance with a section to be measured during measurement of each section.

4. A measurement method of a measurement device including at least two input ports, variable attenuators corresponding to the input ports, and a control unit that attenuates a signal input into the input ports via the variable attenuators by an attenuation amount corresponding to a set input level, the method comprising:
a step of distributing, in measuring an input signal that consists of a plurality of sections and that has different signal levels in each section, the input signal to be measured to all of the input ports;
a step of setting an input level corresponding to each section in each input port; and
a step of measuring each section using an input signal of an input port for which the input level corresponding to each section is set.
